(19) United States
(12) Patent Application Publication
(10) Pub. No.: US 2015/0369880 A1
(43) Pub. Date: Dec. 24, 2015

(54) INDUCTIVE SENSING BASED ON B-H CURVE NONLINIARITY

(71) Applicant: TEXAS INSTRUMENTS INCORPORATED, Dallas, TX (US)

(72) Inventor: Evgeny Fomin, San Carlos, CA (US)

(21) Appl. No.: 14/744,018

(22) Filed: Jun. 18, 2015

Related U.S. Application Data
(60) Provisional application No. 62/013,760, filed on Jun. 18, 2014.

(51) Int. Cl. G01R 33/028

(52) U.S. Cl. CPC G01R 33/028

(57) ABSTRACT

An inductive sensing system is based on nonlinearity of the B-H curve for an inductive sensor with an inductor coil wound onto a magnetic core. A DC magnetic field source magnetically couples into the magnetic core a pre-defined DC magnetic-core field, such that the inductive sensor is configured for a magnetic-core operating point on the B-H curve where the value of the second derivative d²B/dH² is substantially maximum, such that sensing operation is in the nonlinear region around the magnetic-core operating point. An inductance-to-digital conversion (IDC) unit is configured to acquire sensor measurements from the inductor coil corresponding to coil inductance as representing a sensed magnetic-core field. The IDC unit converts the sensor measurements into sensor data corresponding to changes in the sensed magnetic-core field relative to the magnetic-core operating point in response to a sensed condition that affects the DC magnetic field in the magnetic core.

### CROSS-REFERENCE TO RELATED APPLICATIONS

Priority is claimed under USC§119(e) to U.S. Provisional Application No. 62/013,760 (Docket TI-75185PS), filed Jun. 18, 2014.

### BACKGROUND

1. Technical Field

This Patent Document relates generally to sensing physical conditions or states using magnetic fields, such as inductive sensing.

2. Related Art

An inductive sensor includes an inductor coil that establishes an induction loop. An electric current through the inductor coil generates a magnetic field. The inductance of the loop changes according to conditions that affect the magnetic field.

An inductive sensor can be configured with the inductor coil wound onto a magnetic core. A magnetic core is typically formed of a magnetic material with a relatively high permeability, and is used to confine and guide magnetic fields within the inductor core. The high permeability causes the magnetic field lines to be concentrated in the core material.

### BRIEF SUMMARY

This Brief Summary is provided as a general introduction to the Disclosure provided by the Detailed Description and Drawings. It is not a complete overview of the Disclosure, and should not be interpreted as identifying key elements or features of the invention, or otherwise characterizing or delimiting the scope of the invention disclosed in this Patent Document.

The Disclosure provides a written description of apparatus and methods suitable for inductive sensing based on B-H curve nonlinearity. According to aspects of the Disclosure, inductive sensing based on B-H curve nonlinearity can include: (a) configuring a DC magnetic field source to magnetically couple into the magnetic core a pre-defined DC magnetic-core field, such that (1) the inductive sensor is configured for a magnetic-core operating point on the B-H curve where the value of the second derivative d²B/dH² is substantially maximum, and (2) sensing operation is in the nonlinear region around the magnetic-core operating point; (b) acquiring sensor measurements from the inductor coil corresponding to coil inductance as representing a sensed magnetic-core field that is in the nonlinear region around the magnetic-core operating point; and (c) converting the sensor measurements into sensor data corresponding to changes in the sensed magnetic-core field relative to the magnetic-core operating point in response to a sensed condition that affects the DC magnetic field in the magnetic core.

Implementations of the DC magnetic field source can include: (a) at least one permanent magnet positioned relative to the magnetic core to provide the pre-defined DC magnetic field; or (b) a coil coupled to a DC current source that supplies a DC current, the coil is positioned relative to the magnetic core to provide the pre-defined DC magnetic-core field; or (c) a configuration in which a permanent magnet positioned relative to the magnetic core, and configured to provide a DC magnetic field magnetically coupled into the magnetic core, and a ferrous or antiferrous material positioned relative to the magnetic core and the permanent magnet so as to concentrate the DC magnetic field from the permanent magnet, and thereby alter the DC magnetic field in the magnetic core to provide the pre-defined DC magnetic field for sensing operation at the magnetic-core operating point. Implementations of the DC magnetic field source can also include the use of a DC current source coupled through an AC current block to the inductor coil, or to a secondary winding on a transformer/magnetic core that includes the inductor coil as a primary winding, and configured to supply a DC current to provide the DC magnetic-core field to provide the pre-defined DC magnetic field in the transformer/magnetic core.

The method of inductive sensing based on B-H curve nonlinearity can be used to sense conditions that include: (a) inductor coil motion relative to the DC magnetic field source, which affects the sensed DC magnetic-core field in the magnetic core; or (b) proximity of a ferrous or antiferrous target to the inductive sensor which affects the sensed DC magnetic field in the magnetic core; or (c) variations in temperature at the inductive sensor which affects a magnetization state of the magnetic core; or (d) aging of the magnetic core and/or of the DC magnetic field source.

Other aspects and features of the invention claimed in this Patent Document will be apparent to those skilled in the art from the following Disclosure.

### BRIEF DESCRIPTION OF THE DRAWINGS

FIGS. 1A and 1B illustrate example functional embodiments of an inductive sensing assembly 100 suitable for inductive sensing based on B-H curve nonlinearity, including an inductive sensor 110 with an inductor coil 113 wound onto a magnetic core 115, and including a DC magnetic field source 120 configured to magnetically couple into magnetic core 115 a pre-defined DC magnetic-core field, the DC magnetic field source implemented with a permanent magnet 121 and a ferrous or antiferrous material 123.

FIG. 2 illustrates an example plot for a B-H curve 200, including regions 201/203 where inductance is relatively less sensitive to magnetic field changes, a nonlinear region around point 210 in which inductance is most sensitive to changes in external magnetic field strength, where |d²B/dH²| is maximum.

FIG. 3 illustrates an example embodiment in which an inductive sensing assembly 300 is configured with a transformer 311 including a transformer/magnetic core 315, with primary winding L forming a sensor inductor coil 313, and with DC magnetic field source 320 implemented with a secondary winding W on transformer/magnetic core 315, coupled through AC current block 326/327 to a DC current source 329, and configured to supply to the secondary winding W a current to provide a pre-defined DC magnetic-core field in transformer/magnetic core 315.

FIG. 4 illustrates an example embodiment in which a DC magnetic field source 320 is implemented with a DC current source 329 coupled through AC current block 326/327 directly to inductor coil 313, and configured to supply to inductor coil 313 a current to provide a pre-defined DC magnetic-core field in magnetic core 315.

### DETAILED DESCRIPTION

This Description and the Drawings provides a Disclosure of example embodiments and applications that illustrate various features and advantages of inductive sensing based on B-H curve nonlinearity.

In brief overview, an inductive sensing system is based on nonlinearity of the B-H curve for an inductive sensor with an inductor coil wound onto a magnetic core. A DC magnetic field source magnetically couples into the magnetic core a pre-defined DC magnetic-core field, such that the inductive sensor is configured for a magnetic-core operating point on the B-H curve where the value of the second derivative d²B/dH² is substantially maximum, such that sensing operation is in the nonlinear region around the magnetic-core operating point. An inductance-to-digital conversion (IDC) unit is configured to acquire sensor measurements from the inductor coil corresponding to coil inductance as representing a sensed magnetic-core field. The IDC unit converts the sensor measurements into sensor data corresponding to changes in the sensed magnetic-core field relative to the magnetic-core operating point in response to a sensed condition that affects the DC magnetic field in the magnetic core.

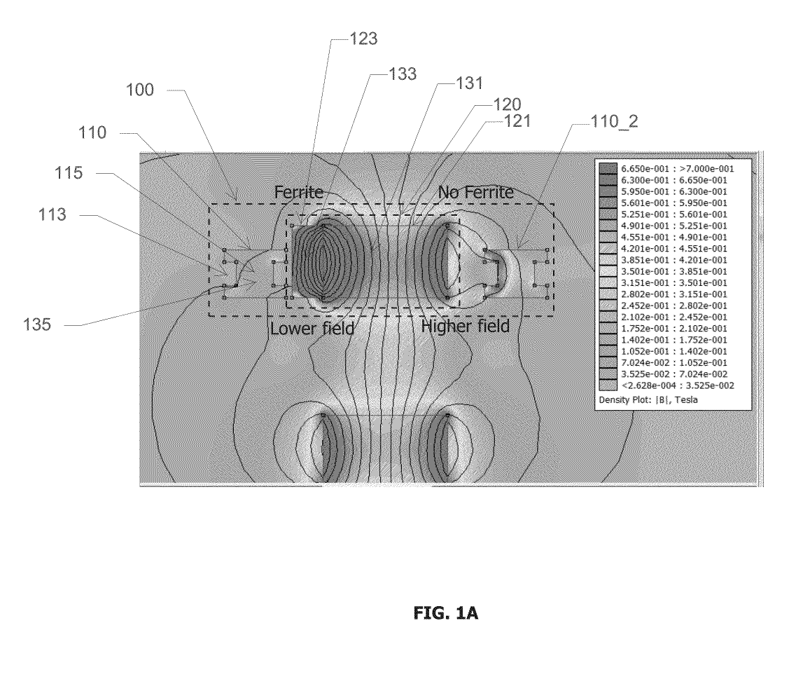

FIGS. 1A and 1B illustrate example functional embodiments with an inductive sensing assembly 100 suitable for inductive sensing based on B-H curve nonlinearity. Inductive sensing assembly 100 includes an inductive sensor 110 with an inductor coil 113 wound onto a magnetic core 115, although to simplify the illustrations, the actual windings of inductor coil 113 are not shown.

Magnetic core 113 is formed of a material exhibiting electromagnetic permeability, such as ferromagnetic, antiferromagnetic or ferrimagnetic materials. Magnetic core 113 is characterized by a B-H curve.

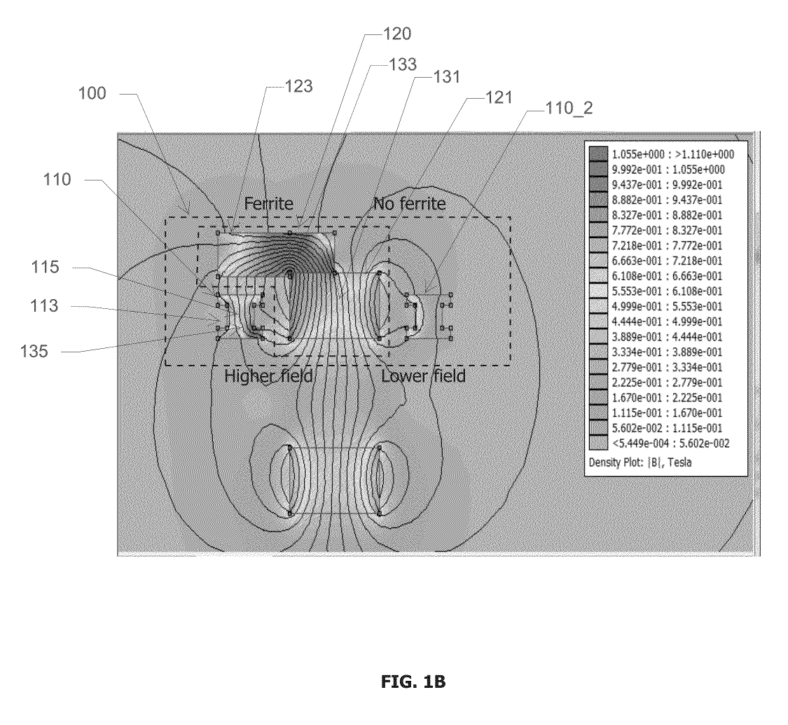

FIG. 2 illustrates an example plot for a B-H curve 200. B-H curve 200 includes regions 201/203 where inductance is relatively less sensitive to magnetic field changes, because magnetic permeability (B/H) is relatively constant.

B-H curve 200 includes a nonlinear region around point 210 in which inductance is most sensitive to changes in external magnetic field strength. Specifically, inductance is most sensitive at point 210 where Id²B/dH²I is maximum.

According to aspects of the Disclosure, inductive sensing is based on B-H curve nonlinearity. Specifically, the inductive sensor (such as 100) is configured for sensing operation with a pre-defined DC magnetic-core field that corresponds to a magnetic-core operating point 210 on the B-H curve where the value of the second derivative d²B/dH² is substantially maximum. Sensing operation is in the nonlinear region around the magnetic-core operating point 210.

Referring back to FIGS. 1A/1B, inductive sensing assembly 100 includes a DC magnetic field source 120 configured to magnetically couple into magnetic core 115 a pre-defined DC magnetic-core field that corresponds to a magnetic-core operating point (FIG. 2, 210). In the example functional embodiments illustrated in FIGS. 1A/1B, DC magnetic field source 120 includes a permanent magnet 121 and a ferrous or antiferrous material 123.

Permanent magnet 121 is positioned relative to magnetic core 115, and configured to provide a DC magnetic field (illustrated by field lines 131) that is magnetically coupled into the magnetic core. The ferrous/antiferrous material 123 is positioned relative to magnetic core 105 and permanent magnet 121 so as to concentrate the DC magnetic field from the permanent magnet (illustrated by field lines 133), and thereby alter the DC magnetic field in the magnetic core to provide the pre-defined DC magnetic field (illustrated by field lines 135) for sensing operation at the magnetic-core operating point (FIG. 2, 210).

For the example functional embodiment in FIG. 1A, DC magnetic field source 120 includes a ferrous/antiferrous material 123 that is positioned relative to the permanent magnet 121 and inductive sensor 101 such that the DC magnetic field magnetically coupled into magnetic core 105 is decreased. For the example functional embodiment in FIG. 1B, DC magnetic field source 120 includes a ferrous/antiferrous material 123 that is positioned relative to the permanent magnet 121 and inductive sensor 101 such that the DC magnetic field magnetically coupled into magnetic core 105 is increased. In either case, the ferrous/antiferrous material 123 is used to alter the DC magnetic field in the magnetic core 115 of the inductive sensor 110 to provide the pre-defined DC magnetic field (illustrated by field lines 135) for sensing operation at the magnetic-core operating point (FIG. 2, 210).

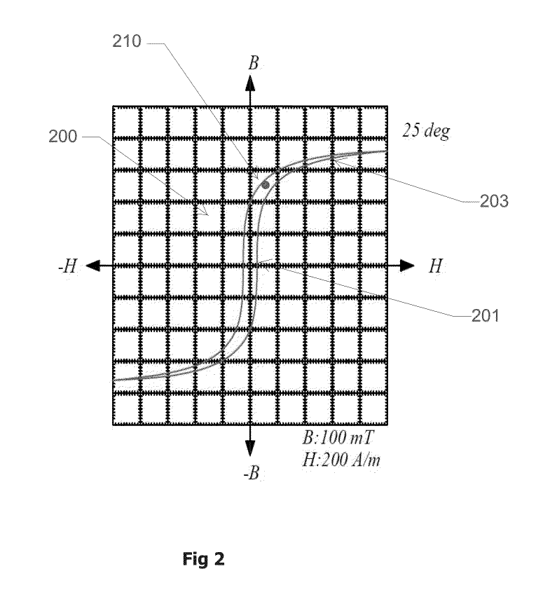

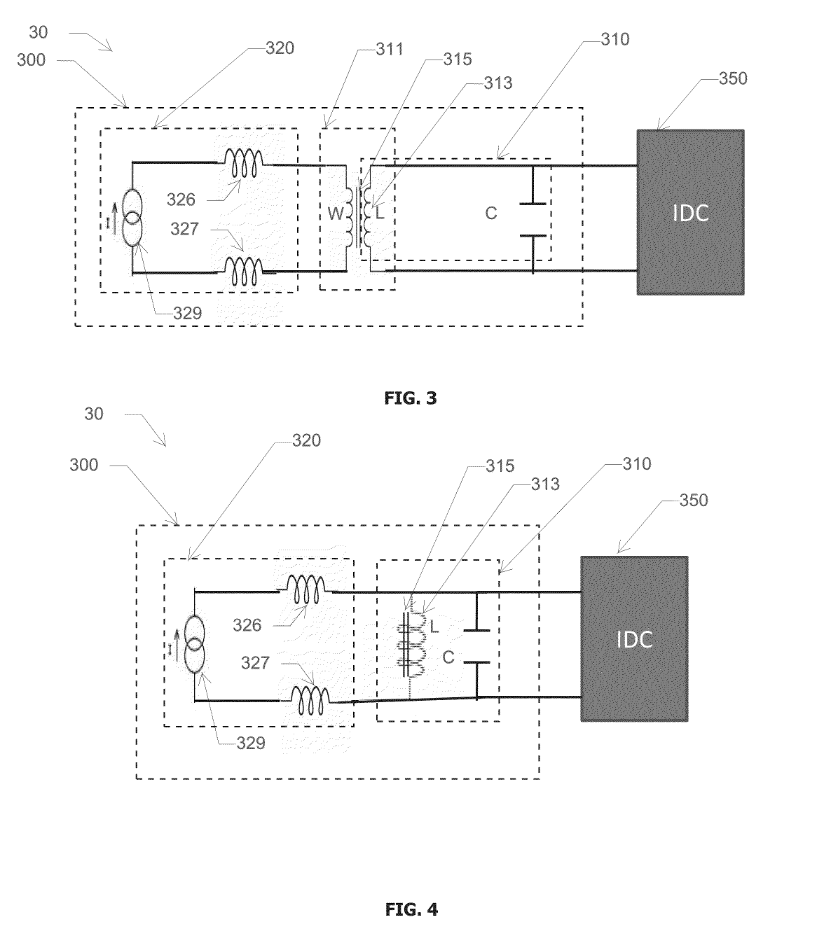

Alternative implementations of the DC magnetic field source include: (a) a single permanent magnet that is constructed to provide the pre-defined DC magnetic field; or (b) a coil coupled to a DC current source that supplies a DC current, with the coil positioned relative to the magnetic core to provide the pre-defined DC magnetic-core field; or (c) a DC current source coupled through an AC current block to the inductor coil in parallel with the IDC unit, and configured to supply to the inductor coil a DC current to provide the DC magnetic-core field (example embodiments of which are described in connection with FIGS. 3 and 4).

As illustrated in FIGS. 1A/1B, a sensing assembly can include multiple inductive sensors, as represented by inductive sensors 110 and 110_2. In FIG. 1A, ferrous/antiferrous material 123 is positioned relative to inductive sensor 101, such that the DC magnetic field in in magnetic core 105 is lower than the DC magnetic field in the magnetic core of sensor 101_2. In FIG. 1B, ferrous/antiferrous material 123 is positioned relative to inductive sensor 110 such that the DC magnetic field in in magnetic core 105 is higher than the DC magnetic field in the magnetic core of sensor 110_2.

From above, the inductive sensor 100 is configured for sensing operation with a pre-defined DC magnetic-core field that corresponds to a magnetic-core operating point on the B-H curve where the value of the second derivative d²B/dH² is substantially maximum (FIG. 2, 210). Sensing operations are in the nonlinear region around the magnetic-core operating point.

Sensing operations measure a sensed condition that causes changes in the sensed magnetic-core field 135 within inductive sensor 101 (magnetic core 115). Specifically, the sensed condition causes changes in the sensed magnetic-core field 135 relative to the magnetic-core operating point (FIG. 2, 210), i.e., within the nonlinear region around the magnetic-core operating point.

Examples of sensed conditions that affect the DC magnetic field 135 within the magnetic core 105 of inductive sensor 110 include: (a) motion of the inductive sensor (inductor coil 113) relative to DC magnetic field source 120, which affects the sensed DC magnetic-core field in the magnetic core; or (b) proximity of a ferrous or antiferrous target to the inductive sensor which affects the sensed DC magnetic field 135 in the magnetic core; or (c) variations in temperature at the inductive sensor which affects a magnetization state of the magnetic core; or (d) aging of the magnetic core and/or of the DC magnetic field source.

For sensing operations, the inductive sensor 101 (inductor coil 113) is coupled to sensor electronics, referred to in this Disclosure as an inductance-to-digital conversion (IDC) unit. An IDC unit is not illustrated in the example embodiments of FIGS. 1A/1B, but is illustrated in the example embodiments of FIGS. 3 and 4.

Referring to FIGS. 1A/1B, an IDC unit can be configured to acquire sensor measurements from the inductive sensor 110 (inductor coil 113). For example, an IDC unit can be configured to acquire sensor measurements corresponding to coil inductance as representing a sensed magnetic-core field 135 in the magnetic core 115. The IDC unit can be configured to convert the sensor measurements into sensor data corresponding to changes in the sensed magnetic-core field 135 relative to the magnetic-core operating point (FIG. 2, 210) in response to a sensed condition that affects the sensed DC magnetic field in magnetic core 115.

FIGS. 3 and 4 illustrate example embodiments of an inductive sensing system 30 that includes an inductive sensor 300. Inductive sensing assembly 300 includes an inductive sensor 310 and a DC magnetic field source 320. DC magnetic field source 320 is coupled to inductive sensor 310 through an AC current block implemented with large inductors 326 and 327.

Inductive sensor 310 is configured for resonant inductive sensing, including an LC resonator that incorporates an inductor coil 313 wound onto a magnetic core 315. An IDC 350 is configured to drive inductor coil 313 with an excitation signal to generate a time-varying magnetic field used to acquire the sensor measurements based on changes in a resonance state of the sensor resonator.

For example, IDC 350 can be configured to drive the inductive sensor/resonator 310 with an AC excitation current synchronized with resonator oscillation voltage to maintain resonance (sustained, steady-state oscillation), overcoming a resonator loss factor represented by a resonator impedance (such as series/parallel resistance Rs/Rp). Resonant sensing is based on changes in resonance state manifested by, for example, changes in resonator oscillation amplitude and frequency resulting from changes in resonator impedance in response to sensed condition.

FIG. 3 illustrates an example embodiment in which inductive sensing assembly 300 is configured with a transformer 311 including a transformer/magnetic core 315. A primary winding L forms the sensor inductor coil 313. DC magnetic field source 320 is implemented with a secondary winding W on transformer/magnetic core 315, coupled through AC current block 326/327 to a DC current source 329. DC magnetic field source 320 is configured to supply to the secondary winding W a current to provide the pre-defined DC magnetic-core field in transformer/magnetic core 315.

FIG. 4 illustrates an example embodiment in which DC magnetic field source 320 is implemented with a DC current source 329 coupled through AC current block 326/327 directly to inductor coil 313. DC magnetic field source 320 is configured to supply to inductor coil 313 a current to provide the pre-defined DC magnetic-core field in magnetic core 315.

In brief summary, the foregoing describes inductive sensing based on B-H curve nonlinearity, according to aspects of this Disclosure. Inductive sensing can be implemented in a system suitable that includes an inductive sensor assembly and a DC magnetic field source. The inductive sensor assembly includes an inductor coil wound onto a magnetic core, characterized by a B-H curve. The DC magnetic field source is configured to magnetically couple into the magnetic core a pre-defined DC magnetic-core field, such that (a) the inductive sensor is configured for a magnetic-core operating point on the B-H curve where the value of the second derivative d²B/dH² is substantially maximum, and (b) sensing operation is in the nonlinear region around the magnetic-core operating point. An inductance-to-digital conversion (IDC) unit coupled to the inductor coil is configured to acquire sensor measurements from the inductor coil corresponding to coil inductance as representing a sensed magnetic-core field that is in the nonlinear region around the magnetic-core operating point, and to convert the sensor measurements into sensor data corresponding to changes in the sensed magnetic-core field relative to the magnetic-core operating point in response to a sensed condition that affects the DC magnetic field in the magnetic core.

In example embodiments, the DC magnetic field source comprises one of: (a) at least one permanent magnet positioned relative to the magnetic core to provide the pre-defined DC magnetic field; or (b) a coil coupled to a DC current source that supplies a DC current, the coil is positioned relative to the magnetic core to provide the pre-defined DC magnetic-core field; or (c) a DC current source coupled through an AC current block to the inductor coil in parallel with the IDC unit, and configured to supply to the inductor coil a DC current to provide the DC magnetic-core field.

In other example embodiments, the DC magnetic field source can be implemented with (a) a permanent magnet positioned relative to the magnetic core, and configured to provide a DC magnetic field magnetically coupled into the magnetic core, and (b) a ferrous or antiferrous material positioned relative to the magnetic core and the permanent magnet so as to concentrate the DC magnetic field from the permanent magnet, and thereby alter the DC magnetic field in the magnetic core to provide the pre-defined DC magnetic field for sensing operation at the magnetic-core operating point.

In other example embodiments, the inductive sensor can be implemented with a transformer with a transformer core and a primary winding forming the sensor inductor coil, and the DC magnetic field source can be implemented with a secondary winding on the transformer core, coupled through an AC current block to a DC current source to provide the pre-defined DC magnetic field in the transformer core.

Inductive sensing based on B-H curve nonlinearity according to aspects of this Disclosure can be used to sense conditions such as: (a) inductor coil motion relative to the DC magnetic field source, which affects the sensed DC magnetic-core field in the magnetic core; or (b) proximity of a ferrous or antiferrous target to the inductive sensor which affects the sensed DC magnetic field in the magnetic core; or (c) variations in temperature at the inductive sensor which affects a magnetization state of the magnetic core; or (d) aging of the magnetic core and/or of the DC magnetic field source.

The Disclosure provided by this Description and the Figures sets forth example embodiments and applications illustrating aspects and features of the invention, and does not limit the scope of the invention, which is defined by the claims. Known circuits, functions and operations are not described in detail to avoid obscuring the principles and features of the invention. These example embodiments and applications can be used by ordinarily skilled artisans as a basis for modifications, substitutions and alternatives to construct other embodiments, including adaptations for other applications.

1. A system suitable for inductive sensing, comprising
an inductive sensor assembly including an inductor coil wound onto a magnetic core, characterized by a B-H curve;
a DC magnetic field source configured to magnetically couple into the magnetic core a pre-defined DC magnetic-core field, such that
the inductive sensor is configured for a magnetic-core operating point on the B-H curve where the value of the second derivative d²B/dH² is substantially maximum, and
sensing operation is in the nonlinear region around the magnetic-core operating point;
an inductance-to-digital conversion (IDC) unit coupled to the inductor coil, and configured to
acquire sensor measurements from the inductor coil corresponding to coil inductance as representing a sensed magnetic-core field that is in the nonlinear region around the magnetic-core operating point; and
convert the sensor measurements into sensor data corresponding to changes in the sensed magnetic-core field relative to the magnetic-core operating point in response to a sensed condition that affects the DC magnetic field in the magnetic core.

2. The system of claim 1, wherein the magnetic core is one of ferromagnetic, antiferromagnetic or ferrimagnetic.

3. The system of claim 1, wherein the DC magnetic field source comprises one of:
at least one permanent magnet positioned relative to the magnetic core to provide the pre-defined DC magnetic field; or
a coil coupled to a DC current source that supplies a DC current, the coil is positioned relative to the magnetic core to provide the pre-defined DC magnetic-core field; or
a DC current source coupled through an AC current block to the inductor coil in parallel with the IDC unit, and configured to supply to the inductor coil a DC current to provide the DC magnetic-core field.

4. The system of claim 1, wherein the DC magnetic field source comprises:
a permanent magnet positioned relative to the magnetic core, and configured to provide a DC magnetic field magnetically coupled into the magnetic core; and
a ferrous or antiferrous material positioned relative to the magnetic core and the permanent magnet so as to concentrate the DC magnetic field from the permanent magnet, and thereby alter the DC magnetic field in the magnetic core to provide the pre-defined DC magnetic field for sensing operation at the magnetic-core operating point.

5. The system of claim 1,
wherein the inductive sensor comprises a transformer with a transformer core and a primary winding forming the sensor inductor coil; and
wherein the DC magnetic field source comprises a secondary winding on the transformer core, coupled through an AC current block to a DC current source to provide the pre-defined DC magnetic field in the transformer core.

6. The system of claim 1,
wherein the inductive sensor is configured for resonant inductive sensing, including a sensor resonator that incorporates the inductor coil;
wherein the IDC unit is configured to drive the inductor coil with an excitation signal to generate a time-varying magnetic field used to acquire the sensor measurements based on changes in a resonance state of the sensor resonator.

7. The system of claim 1, wherein the sensed condition that changes the DC magnetic field in the magnetic core is one of:
inductor coil motion relative to the DC magnetic field source, which affects the sensed DC magnetic-core field in the magnetic core; or
proximity of a ferrous or antiferrous target to the inductive sensor which affects the sensed DC magnetic field in the magnetic core; or
variations in temperature at the inductive sensor which affects a magnetization state of the magnetic core; or
aging of the magnetic core and/or of the DC magnetic field source.

8. An inductance-to-digital conversion (IDC) circuit suitable for use with an inductive sensor assembly that includes an inductive sensor unit including an inductor coil wound onto a magnetic core, characterized by a B-H curve, and a DC magnetic field source configured to magnetically couple into the magnetic core a pre-defined DC magnetic-core field, such that the inductive sensor is configured for a magnetic-core operating point on the B-H curve where the value of the second derivative d²B/dH² is substantially maximum, and sensing operation is in the nonlinear region around the magnetic-core operating point, the IDC circuit comprising;
acquisition circuitry configured to acquire sensor measurements from the inductor coil corresponding to coil inductance as representing a sensed magnetic-core field that is in the nonlinear region around the magnetic-core operating point; and
data conversion circuitry configured to convert the sensor measurements into sensor data corresponding to changes in the sensed magnetic-core field relative to the magnetic-core operating point in response to a sensed condition that affects the DC magnetic field in the magnetic core.

9. The circuit of claim 8, wherein the magnetic core is one of ferromagnetic, antiferromagnetic or ferrimagnetic.

10. The circuit of claim 8, wherein the DC magnetic field source comprises one of:
at least one permanent magnet positioned relative to the magnetic core to provide the pre-defined DC magnetic field; or
a coil coupled to a DC current source that supplies a DC current, the coil is positioned relative to the magnetic core to provide the pre-defined DC magnetic-core field; or
a DC current source coupled through an AC current block to the inductor coil in parallel with the IDC unit, and configured to supply to the inductor coil a DC current to provide the DC magnetic-core field.

11. The circuit of claim 8, wherein the DC magnetic field source comprises:
a permanent magnet positioned relative to the magnetic core, and configured to provide a DC magnetic field magnetically coupled into the magnetic core; and
a ferrous or antiferrous material positioned relative to the magnetic core and the permanent magnet so as to concentrate the DC magnetic field from the permanent magnet, and thereby alter the DC magnetic field in the magnetic core to provide the pre-defined DC magnetic field for sensing operation at the magnetic-core operating point.

12. The circuit of claim 8,
wherein the inductive sensor comprises a transformer with a transformer core and a primary winding forming the sensor inductor coil; and
wherein the DC magnetic field source comprises a secondary winding on the transformer core, coupled through an AC current block to a DC current source to provide the pre-defined DC magnetic field in the transformer core.

13. The circuit of claim 1,
wherein the inductive sensor is configured for resonant inductive sensing, including a sensor resonator that incorporates the inductor coil;
wherein the IDC unit is configured to drive the inductor coil with an excitation signal to generate a time-varying magnetic field used to acquire the sensor measurements based on changes in a resonance state of the sensor resonator.

14. The circuit of claim 1, wherein the sensed condition that changes the DC magnetic field in the magnetic core is one of:
inductor coil motion relative to the DC magnetic field source, which affects the sensed DC magnetic-core field in the magnetic core; or
proximity of a ferrous or antiferrous target to the inductive sensor which affects the sensed DC magnetic field in the magnetic core; or
variations in temperature at the inductive sensor which affects a magnetization state of the magnetic core; or
aging of the magnetic core and/or of the DC magnetic field source.

15. A method suitable for inductive sensing using an inductive sensor including an inductor coil wound onto a magnetic core, characterized by a B-H curve, comprising
configuring a DC magnetic field source to magnetically couple into the magnetic core a pre-defined DC magnetic-core field, such that
the inductive sensor is configured for a magnetic-core operating point on the B-H curve where the value of the second derivative d²B/dH² is substantially maximum, and
sensing operation is in the nonlinear region around the magnetic-core operating point;
acquiring sensor measurements from the inductor coil corresponding to coil inductance as representing a sensed magnetic-core field that is in the nonlinear region around the magnetic-core operating point; and
converting the sensor measurements into sensor data corresponding to changes in the sensed magnetic-core field relative to the magnetic-core operating point in response to a sensed condition that affects the DC magnetic field in the magnetic core.

16. The method of claim 15, wherein the DC magnetic field source comprises one of:
at least one permanent magnet positioned relative to the magnetic core to provide the pre-defined DC magnetic field; or
a coil coupled to a DC current source that supplies a DC current, the coil is positioned relative to the magnetic core to provide the pre-defined DC magnetic-core field; or
a DC current source coupled through an AC current block to the inductor coil in parallel with the IDC unit, and configured to supply to the inductor coil a DC current to provide the DC magnetic-core field.

17. The method of claim 15, wherein the DC magnetic field source comprises:
a permanent magnet positioned relative to the magnetic core, and configured to provide a DC magnetic field magnetically coupled into the magnetic core; and
a ferrous or antiferrous material positioned relative to the magnetic core and the permanent magnet so as to concentrate the DC magnetic field from the permanent magnet, and thereby alter the DC magnetic field in the magnetic core to provide the pre-defined DC magnetic field for sensing operation at the magnetic-core operating point.

18. The method of claim 1,
wherein the inductive sensor comprises a transformer with a transformer core and a primary winding forming the sensor inductor coil; and
wherein the DC magnetic field source comprises a secondary winding on the transformer core, coupled through an AC current block to a DC current source to provide the pre-defined DC magnetic field in the transformer core.

19. The method of claim 1,
wherein the inductive sensor is configured for resonant inductive sensing, including a sensor resonator that incorporates the inductor coil;
wherein the IDC unit is configured to drive the inductor coil with an excitation signal to generate a time-varying magnetic field used to acquire the sensor measurements based on changes in a resonance state of the sensor resonator.

20. The method of claim 1, wherein the sensed condition that changes the DC magnetic field in the magnetic core is one of:
inductor coil motion relative to the DC magnetic field source, which affects the sensed DC magnetic-core field in the magnetic core; or
proximity of a ferrous or antiferrous target to the inductive sensor which affects the sensed DC magnetic field in the magnetic core; or
variations in temperature at the inductive sensor which affects a magnetization state of the magnetic core; or
aging of the magnetic core and/or of the DC magnetic field source.
